(19) United States
(12) Patent Application Publication
(10) Pub. No.: US 2013/0303264 A1
(43) Pub. Date: Nov. 14, 2013

(54) COOLING CHASSIS FOR A GAMING MACHINE

(71) Applicants: Stephen G. Gill, Sparks, NV (US); Jerrod L. Laputz, Sparks, NV (US)

(72) Inventors: Stephen G. Gill, Sparks, NV (US); Jerrod L. Laputz, Sparks, NV (US)

(73) Assignee: IGT, Reno, NV (US)

(21) Appl. No.: 13/467,712

(22) Filed: May 9, 2012

(51) Int. Cl. A63F 13/00; H05K 7/20; H05K 5/02

(52) U.S. Cl. 463/25; 312/236

(57) ABSTRACT

Disclosed herein is a wager-based gaming machine having a chassis configured to house an internal electronic component of the gaming machine. The chassis includes a cooling assembly. The cooling assembly has a first heat exchanger coupled to the internal electronic component and a fluid communication path situated proximate to a chassis wall. The fluid communication path is configured to transfer thermal energy from the first heat exchanger to an exterior region of the chassis via the chassis wall to maintain an operational temperature of the internal electronic component.

### TECHNICAL FIELD

The present disclosure relates generally to a cooling chassis that provides a mechanism to cool internal electronic components of a gaming machine.

### BACKGROUND

There are a wide variety of associated devices that can be connected to a gaming machine such as a slot machine or video poker machine. Some examples of these devices are lights, ticket printers, card readers, speakers, bill validators, ticket readers, coin acceptors, display panels, key pads, coin hoppers and button pads. Many of these devices are built into the gaming machine or components associated with the gaming machine such as a top box which usually sits on top of the gaming machine.

Typically, utilizing a master gaming controller, the gaming machine controls various combinations of devices that allow a player to play a game on the gaming machine and also encourage game play on the gaming machine. For example, a game played on a gaming machine usually requires a player to input money or indicia of credit into the gaming machine, indicate a wager amount, and initiate a game play. These steps require the gaming machine to control input devices, including bill validators and coin acceptors, to accept money into the gaming machine and recognize user inputs from various devices, including key pads and button pads, to determine the wager amount and initiate game play. After game play has been initiated, the gaming machine determines a game outcome, presents the game outcome to the player and may dispense an award of some type depending on the outcome of the game.

As technology in the gaming industry progresses, the modern electronic gaming machine provides more complex games with complicated graphics, videos, music, and other features to heighten the entertainment experience provided to a player. To provide such complex games, the electronic gaming machine utilizes numerous internal electronic components including, for example, a central processing unit (CPU), a graphics processing unit (GPU), a platform controller hub (PCH), a power supply, a monitor, a communication board, and a sound system. As such, these internal electronic components consume a significant amount of power and dissipate an increased amount of heat. Thus, there is a need for some form of thermal management of the internal electronic components to ensure that the component's operational temperature is maintained to prevent premature component failure.

Typically, modern electronic gaming machines use a combination of natural convection and forced convection to prevent internal electronic components from overheating and failing. A gaming machine cabinet will include vents near the top, and/or the bottom of the cabinet. As hot air is generated within the gaming machine cabinet, internal cooling fans draw air through, for example, vents on the bottom of the cabinet to cool the internal electronic components and expel air through vents at the top of the cabinet. However, a problem associated with this design is that internal particulates and contaminates can often circulate within the gaming machine and adhere to devices designed to dissipate heat from internal electronic components. For example, the particulates and contaminates may adhere to heat sinks, heat spreaders or cooling fans. As such, the particulates and contaminates create an insulating layer on the surfaces of the heat dissipating devices that diminishes the devices' ability to transfer heat. Furthermore, as air is pulled into the gaming machine, particulates can form deposits on the intake vents of a gaming machine, eventually impeding airflow to cool the internal electronic components. As a consequence, internal electronic components (e.g., a CPU) can overheat and fail.

FIG. 1 shows a CPU chassis 100 that houses a CPU (not shown). Typically, the CPU chassis 100 is located within a gaming machine cabinet. The CPU chassis 100 includes a chassis fan 104 that allows air 106 from the gaming machine cabinet to flow into the CPU chassis 100 to cool the CPU. Additionally, the chassis fan 104 cools the interior of the chassis by moving air 106 over components within the chassis. Then, the air 106 flows out of the chassis 100 via a vent 108. The CPU chassis 100 also includes a lid 110 to provide access to the interior of the chassis. The CPU chassis further includes a fan sink 112 coupled on top of the CPU. The fan sink includes a cooling fan 114 coupled to a heat sink 116 that are used to cool the CPU.

As previously noted, a problem associated with current designs is that internal particulates and contaminates can often deposit in the bearings of the chassis fan 104 and adhere to parts of the fan sink 112, thereby lowering cooling efficiency of the heat dissipating devices. Typically in a casino, for example, there is nicotine, textile fibers, dust, dirt and other contaminates that circulate in the air due to people smoking and moving about in the casino. These contaminates are drawn into a gaming machine cabinet by natural or forced convection and flow into the CPU chassis via the fan 104. As such, these contaminates accumulate and form deposits on the surfaces of various components and devices within the chassis 100 instead of exiting the chassis. For instance, nicotine can accumulate and create sticky surfaces on the fan sink 112. As a result, other contaminates, such as textile fibers or dust can adhere onto surfaces where there is an accumulation of nicotine. The contaminate accumulation on the fan sink may create an insulating layer that inhibits efficient heat transfer. Contaminate buildup also inhibits airflow through the heat sink 116 fin passageways that results in lowering the cooling efficiency of the fan sink. In yet another example, dust and internal particulates can form deposits on the bearing of the fans 104 and 114 causing the fans to fail. Similarly, dust and internal particulates can form deposits on intake fans of a gaming machine, thereby impeding air to flow into the gaming machine. As a result, the CPU and other components within the chassis 100 may overheat and also fail.

Generally, in a gaming environment, a CPU chassis, for example, needs to be accessed by casino service technicians to service components such as the motherboard or other components housed in the chassis. However, accessing an interior region of a chassis can be challenging as access may be obstructed by a heat sink, a cooling fan, internal electronic components, a memory component or any other component housed within the chassis.

For example, a CPU chassis may use a heat pipe assembly that includes a heat pipe and heat spreaders to cool internal electronic components, such as a CPU and a GPU. Typically, in such a configuration, the heat pipe is coupled to the chassis lid using a thermal interface. When a casino service technician removes the chassis lid to access the interior region of the chassis, the bond provided by the thermal interface is disturbed. For instance, the connection between the heat pipe and the chassis lid may be loosened, which may cause the heat pipe to separate from the lid. In some instances, opening the chassis lid may disrupt the thermal interface between the heat spreader and the CPU and GPU, requiring replacement of the thermal interface, the heat spreader, the CPU and/or the GPU. As such, servicing components housed in a chassis can be burdensome and cost ineffective.

Accordingly, in view of the foregoing, it would be desirable to provide a technique to reliably cool internal electronic components of a gaming machine without such internal components prematurely failing due to thermal overloads and particulate contamination. Additionally, it would be desirable to provide unobstructed access to the interior of a chassis without disturbing the internal components housed in the chassis.

### SUMMARY

Various embodiments described or referenced herein are directed to a cooling system for a gaming machine. In some embodiments, the gaming machine may be configured or designed for use in a casino environment.

In some implementations, a gaming machine may comprise an input device configured to receive an indication of value for play of a wager-based game in which one or more game outcomes can be provided responsive to a wager, an output device configured to output an indication of value in association with play of the wager-based game, and a display configured to display information associated with the wager-based game. The gaming machine may further comprise a chassis configured to house an internal electronic component of the gaming machine. The chassis may include a chassis wall and an access panel to provide access to the internal electronic component and a cooling assembly. The cooling assembly may include a first heat exchanger coupled to the internal electronic component and a fluid communication path situated proximate to the chassis wall. The fluid communication path may be configured to transfer thermal energy from the first heat exchanger to an exterior region of the chassis via the chassis wall to maintain an operational temperature of the internal electronic component.

In various implementations, the fluid communication path may further include a high temperature end and a low temperature end. The fluid communication path may be configured to house a working fluid. The working fluid may be at least one of water, ethanol, acetone or sodium.

In various implementations, the first heat exchanger may be coupled to the fluid communication path at the high temperature end, and the first heat exchanger may be further configured to transfer thermal energy from the internal electronic component to the high temperature end of the fluid communication path to cause the working fluid to evaporate.

In various implementations, the low temperature end of the fluid communication path may be further coupled to the chassis wall, and the chassis wall may be further configured to receive thermal energy from the first heat exchanger at the low temperature end of the fluid communication path to cause the vapor to condense back into the working fluid.

In various implementations, the cooling assembly may further include a second heat exchanger situated proximate to the chassis wall at the low temperature end of the fluid communication path, and the first heat exchanger may be coupled to the second heat exchanger. The second heat exchanger may be configured to receive thermal energy from the first heat exchanger via the fluid communication path and transfer thermal energy to the chassis wall.

In various implementations, the second heat exchanger may be configured to be thermally coupled to the chassis wall to transfer thermal energy by conduction through the chassis wall. In yet some other implementations, the second heat exchanger may be thermally coupled to the chassis wall by a thermal interface. The thermal interface may be at least one of: a thermal grease, a thermal pad or a thermal adhesive.

In various implementations, the second heat exchanger may be positioned at a location away from the access panel to provide an unobstructed access to the internal electronic component housed within the chassis.

In various implementations, the chassis wall may include cooling fins to facilitate the transfer of thermal energy to the exterior region of the chassis.

In various implementations, the chassis may be further configured to prevent air from entering into an interior region of the chassis when the access panel is in a closed position.

In various implementations, the first heat exchanger may be coupled to a plurality of internal electronic components located within the chassis based on an optimization factor. The optimization factor may be at least one of: a location of each internal electronic component of the plurality of internal electronic components, a power requirement of each internal electronic component of the plurality of electronic components, and an amount of thermal energy dissipated by each internal electronic component of the plurality of electronic components.

In various implementations, the internal electronic component may be at least one of a central processing unit, a graphical processing unit or a platform controller hub.

In some implementations, a chassis for use with a gaming machine may comprise a chassis wall and an access panel to provide access to an internal electronic gaming machine component located within the chassis and a cooling assembly. The cooling assembly may include a first heat exchanger thermally coupled to the internal electronic gaming machine component and a fluid communication path situated proximate to the chassis wall. The fluid communication path may be configured to transfer thermal energy from the first heat exchanger to an exterior region of the chassis via the chassis wall to maintain an operational temperature of the internal electronic gaming machine component.

In various implementations, another internal electronic gaming machine component may be coupled to the access panel via a thermal interface.

In various implementations, the chassis may be a stand-alone case housed in a compartment of the gaming machine.

Aspects of the invention may be implemented by networked gaming machines, game servers and other such devices. These and other features and benefits of aspects of the invention will be described in more detail below with reference to the associated drawings. In addition, other features and advantages of the invention will be or will become apparent to one with skill in the art upon examination of the following figures and detailed description. It is intended that all such additional features and advantages be included within this description, be within the scope of the invention, and be protected by the accompanying claims.

### BRIEF DESCRIPTION OF THE DRAWINGS

The included drawings are for illustrative purposes and serve only to provide examples of possible structures and process steps for the disclosed inventive devices and systems for providing a cooling chassis for a gaming machine. These drawings in no way limit any changes in form and detail that may be made to embodiments by one skilled in the art without departing from the spirit and scope of the disclosure.

FIG. 1 shows a prior art chassis housing a CPU employing a conventional cooling fan.

FIGS. 2, 3A, and 3B are perspective diagrams of a gaming machine, configured in accordance with one implementation.

FIGS. 4A-4B show a cooling chassis in accordance with one implementation.

FIGS. 5A-5B illustrate some examples of different implementations of a cooling assembly.

FIG. 6 shows a cooling chassis in accordance with one implementation.

FIG. 7 shows an interior of a gaming machine cabinet housing a plurality of internal electronic gaming components each housed within its own individual chassis.

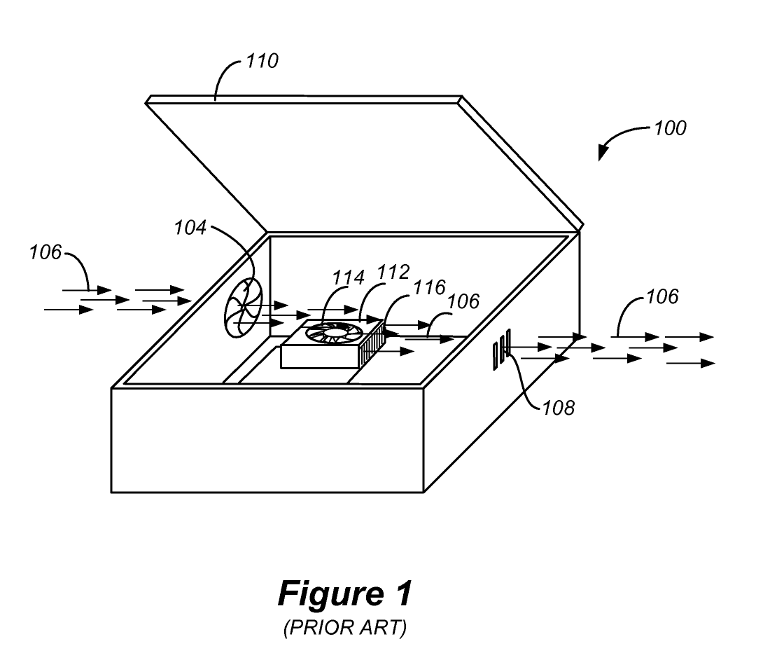

### DETAILED DESCRIPTION

Applications of systems and devices according to one or more embodiments are described in this section. These examples are being provided solely to add context and aid in the understanding of the present disclosure. It will thus be apparent to one skilled in the art that the techniques described herein may be practiced without some or all of these specific details. In other instances, well known process steps have not been described in detail in order to avoid unnecessarily obscuring the present disclosure. Other applications are possible, such that the following examples should not be taken as definitive or limiting either in scope or setting.

In the following detailed description, references are made to the accompanying drawings, which form a part of the description and in which are shown, by way of illustration, specific embodiments. Although these embodiments are described in sufficient detail to enable one skilled in the art to practice the disclosure, it is understood that these examples are not limiting, such that other embodiments may be used and changes may be made without departing from the spirit and scope of the disclosure.

In some implementations, techniques described herein provide a cooling chassis to reliably cool internal components of a gaming machine. A cooling chassis may be used to cool any component or device that generates high temperatures or produce a significant amount of thermal energy. A cooling chassis may house internal electronic components, such as a CPU. The walls of the cooling chassis may be configured to facilitate the cooling of the CPU such that thermal energy or wasted or latent heat is transferred from the internal region of the chassis to an external region of the chassis via conduction, convection and/or radiation. For example, a wall of the cooling chassis may be coupled with a cooling assembly or parts of a cooling assembly to conduct heat from the CPU through the chassis wall. Then, the heat is transferred to an interior of a gaming machine via conduction, convection and/or radiation. By using a wall of a cooling chassis as a conductive medium to transmit heat out of the chassis, the CPU's operational temperature may be maintained without the use of a cooling fan.

In some implementations, the cooling chassis may include an access panel (e.g., a lid) to provide access to an interior region of the chassis. A cooling assembly may be housed within the cooling chassis in a location away from the access panel such that it provides unobstructed access to the interior region of the chassis. The cooling assembly, for example, includes a heat exchanger that is coupled to a wall of the chassis. As such, the access panel may be opened without interfering with the operation of the cooling assembly. The unobstructed access enhances serviceability to the chassis interior and reduces the need to unnecessarily replace parts caused, for instance, by ruining a thermal interface between the access panel and the cooling assembly.

In some implementations, the access panel is configured as a mount for internal electronic components. Securely mounting internal electronic components to an interior side of the access panel allows the components to move with the access panel when the access panel is moved to an open position, resulting in an unobstructed access to the chassis interior. Additionally, in such an implementation, the access panel functions as another medium to transfer thermal energy out of a cooling chassis.

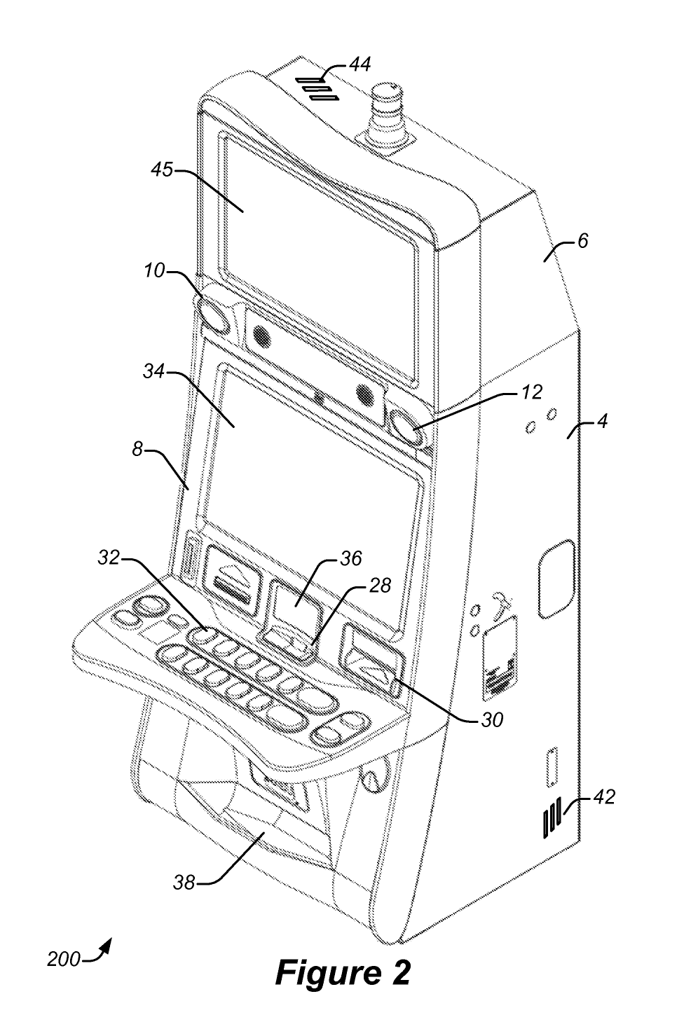

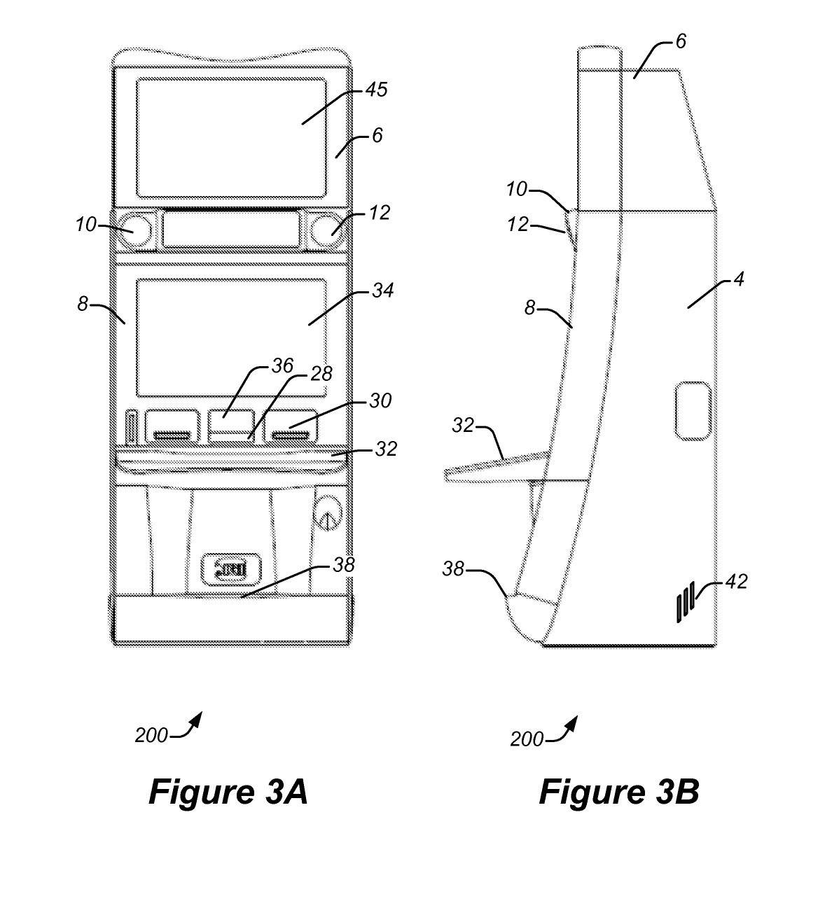

FIGS. 2, 3A, and 3B are perspective diagrams of a gaming machine 200, configured in accordance with one implementation. As illustrated in FIGS. 2, 3A, and 3B, gaming machine 200 includes a main cabinet 4, which generally surrounds the machine interior and is viewable by users. The main cabinet includes a main door 8 on the front of the machine, which opens to provide access to the interior of the machine.

In some implementations, the electronic gaming machine may include any of a plurality of devices. For example, the electronic gaming machine may include a ticket printer that prints bar-coded tickets, a key pad for entering player tracking information, a display (e.g., a video display screen) for displaying player tracking information, a card reader for entering a magnetic striped card containing player tracking information, and any other devices. The ticket printer may be used to print tickets for a cashless ticketing system. In FIGS. 2-3B, attached to the main door is a payment acceptor 28, a bill validator 30, and a coin tray 38. The payment acceptor may include a coin slot and/or a payment, note, or bill acceptor, where the player inserts money, coins, tokens, or other types of payments.

In some implementations, devices such as readers or validators for credit cards, debit cards, smart cards, or credit slips may facilitate payment. For example, a player may insert an identification card into a card reader of the gaming machine. The identification card may be a smart card coded with a player's identification, credit totals (or related data) and other relevant information. As another example, a player may carry a portable device, such as a cell phone, a radio frequency identification tag or any other suitable wireless device. The portable device may communicate a player's identification, credit totals (or related data), and/or any other relevant information to the gaming machine. As yet another example, money may be transferred to a gaming machine through electronic funds transfer. When a player funds the gaming machine, another logic device coupled to the gaming machine may determine the amount of funds entered and display the corresponding amount on a display device.

In some implementations, attached to the main door is a plurality of player-input switches or buttons 32. The input switches can include any suitable devices which enable the player to produce an input signal which is received by a processor or a master gaming controller of the gaming machine. The input switches may include a game activation device that may be used by the player to start any primary game or sequence of events in the gaming machine. The game activation device can be any suitable play activator such as a “bet one” button, a “max bet” button, or a “repeat the bet” button. In some instances, upon appropriate funding, the gaming machine may begin the game play automatically. Alternately, the gaming machine may automatically activate game play after detecting user input via the game activation device.

In some implementations, one input switch is a cash-out button. The player may push the cash-out button and cash out to receive a cash payment or other suitable form of payment corresponding to the number of remaining credits. For example, when the player cashes out, the player may receive the coins or tokens in a coin payout tray. As another example, the player may receive other payout mechanisms such as tickets or credit slips redeemable by a cashier (or other suitable redemption system) or funding to the player's electronically recordable identification card. As yet another example, funds may be transferred from the gaming machine to the player's smart card.

In some implementations, one input switch is a touch-screen coupled with a touch-screen controller, or some other touch-sensitive display overlay to enable for player interaction with the images on the display. The touch-screen and the touch-screen controller may be connected to a video controller. A player may make decisions and input signals into the gaming machine by touching the touch-screen at the appropriate places. One such input switch is a touch-screen button panel.

In some implementations, the gaming machine may include communication ports for enabling communication of the gaming machine processor with external peripherals, such as external video sources, expansion buses, game or other displays, a SCSI port, a key pad, or a network interface for communicating via a network.

In some implementations, the gaming machine may include a label area, such as the label area 36. The label area may be used to display any information or insignia related to activities conducted at the gaming machine.

In some implementations, the electronic gaming machine may include one or more display devices. For example, the electronic gaming machine 200 includes display devices 34 and 45. The display devices 34 and 45 may each include any of a cathode ray tube, an LCD, a light emitting diode (LED) based display, an organic light emitting diode (OLED) based display, a polymer light emitting diode (PLED) based display, an SED based-display, an E-ink display, a plasma display, a television display, a display including a projected and/or reflected image, or any other suitable electronic display device.

In some implementations, the display devices at the gaming machine may include one or more electromechanical devices such as one or more rotatable wheels, reels, or dice. The display device may include an electromechanical device adjacent to a video display, such as a video display positioned in front of a mechanical reel. The display devices may include dual-layered or multi-layered electromechanical and/or video displays that cooperate to generate one or more images. The display devices may include a mobile display device, such as a smart phone or tablet computer, that allows play of at least a portion of the primary or secondary game at a location remote from the gaming machine. The display devices may be of any suitable size and configuration, such as a square, a rectangle or an elongated rectangle.

In some implementations, the display devices of the gaming machine are configured to display game images or other suitable images. The images may include symbols, game indicia, people, characters, places, things, faces of cards, dice, and various other images. The images may include a visual representation or exhibition of the movement of objects such as mechanical, virtual, or video reels and wheels. The images may include a visual representation or exhibition of dynamic lighting, video images, or any other images.

In some implementations, the electronic gaming machine may include a top box. For example, the gaming machine 200 includes a top box 6, which sits on top of the main cabinet 4. The top box 6 may house any of a number of devices, which may be used to add features to a game being played on the gaming machine 200. These devices may include speakers 10 and 12, the display device 45, and any other devices. Further, the top box 6 may house different or additional devices not illustrated in FIGS. 2-3B. For example, the top box may include a bonus wheel or a back-lit silk screened panel which may be used to add bonus features to the game being played on the gaming machine. As another example, the top box may include a display for a progressive jackpot offered on the gaming machine. As yet another example, the top box may include a smart card interaction device. During a game, these devices are controlled and powered, at least in part, by circuitry (e.g. a master gaming controller) housed within the main cabinet 4 of the machine 200.

In some implementations, speakers may be mounted and situated in the cabinet with an angled orientation toward the player. For instance, the speakers 10 and 12 located in top box area 6 of the upper region of gaming machine 200 may be mounted and situated in the cabinet with an angled orientation down towards the player and the floor. In one example, the angle is 45 degrees with respect to the vertical, longitudinal axis of machine 200. In another example, the angle is in a range of 30-60 degrees. In another example, the angle is any angle between 0 and 90 degrees. In some implementations, the angle of speakers in the gaming machine may be adjustable. For instance, speakers may be adjusted to face in a direction more closely approximating an estimated position of a player's head or facial features.

The bill validator 30, the player-input switches 32, the display screen 34, and other gaming devices may be used to present a game on the game machine 200. The devices may be controlled by code executed by the master gaming controller housed inside the main cabinet 4 of the machine 200. The master gaming controller may include one or more processors including general purpose and specialized processors, such as CPUs or graphics cards, and one or more memory devices including volatile and non-volatile memory. The master gaming controller may periodically configure and/or authenticate the code executed on the gaming machine. In some implementations, the master gaming controller may be housed within a cooling chassis as described herein.

In some implementations, the gaming machine may include a sound generating device coupled to one or more sounds cards. The sound generating device may include one or more speakers or other sound generating hardware and/or software for generating sounds, such as playing music for the primary and/or secondary game or for other modes of the gaming machine, such as an attract mode. The gaming machine may provide dynamic sounds coupled with attractive multimedia images displayed on one or more of the display devices to provide an audio-visual representation or to otherwise display full-motion video with sound to attract players to the gaming machine. During idle periods, the gaming machine may display a sequence of audio and/or visual attraction messages to attract potential players to the gaming machine. The videos may also be customized for or to provide any appropriate information.

In some implementations, the gaming machine may include a sensor, such as a camera that is selectively positioned to acquire an image of a player actively using the gaming machine and/or the surrounding area of the gaming machine. The sensor may be configured to capture biometric data about a player in proximity to the gaming machine. The biometric data may be used to implement mechanical and/or digital adjustments to the gaming machine. Alternately, or additionally, the sensor may be configured to selectively acquire still or moving (e.g., video) images. The display devices may be configured to display the image acquired by the camera as well as display the visible manifestation of the game in split screen or picture-in-picture fashion. For example, the camera may acquire an image of the player and the processor may incorporate that image into the primary and/or secondary game as a game image, symbol, animated avatar, or game indicia. In some implementations, the sensor may be used to trigger an attract mode effect. For example, when the sensor detects the presence of a nearby player, the gaming machine may play sound effects or display images, text, graphics, lighting effects, or animations to attract the player to play a game at the gaming machine.

In some implementations, the gaming machine 200 may include one or more vents to allow air to flow through the interior of the gaming machine. For example, the gaming machine 200 may have an air intake vent 42 near the bottom of the gaming machine and an air exhaust vent 44 located at the top box 6. This vent configuration allows cool air to be drawn into the gaming machine through the vent 42. The air may be drawn into the gaming machine cabinet by natural convection and/or forced convection. For example, a cooling fan may be placed within the cabinet of the gaming machine. As internal electronic components generate heat within the gaming machine, the cooling fan draws in air from the vent 42 to cool the internal electronic components. The air then exits through the vent 44. The vents may be located and situated on the gaming machine to enable air circulation across the internal components housed in the gaming machine. The vent locations may vary depending on the location of the components within the gaming machine 200.

Gaming machine 200 is but one example from a wide range of gaming machine designs on which the techniques described herein may be implemented. For example, not all suitable gaming machines have top boxes or player tracking features. Further, some gaming machines have only a single game display—mechanical or video, while others may have multiple displays.

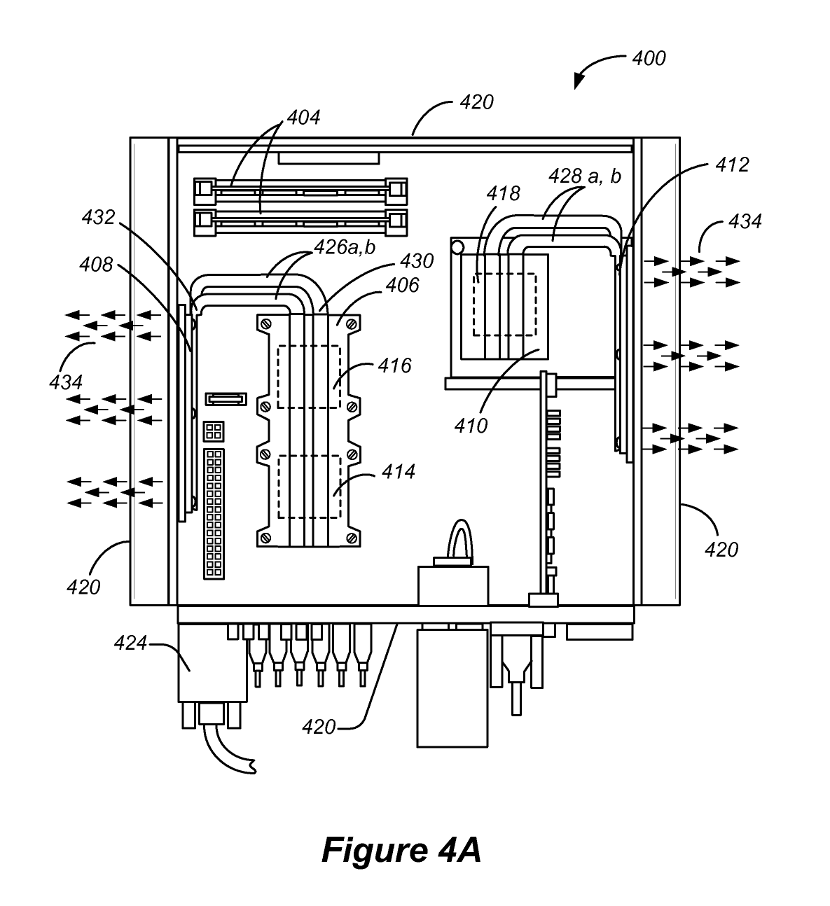

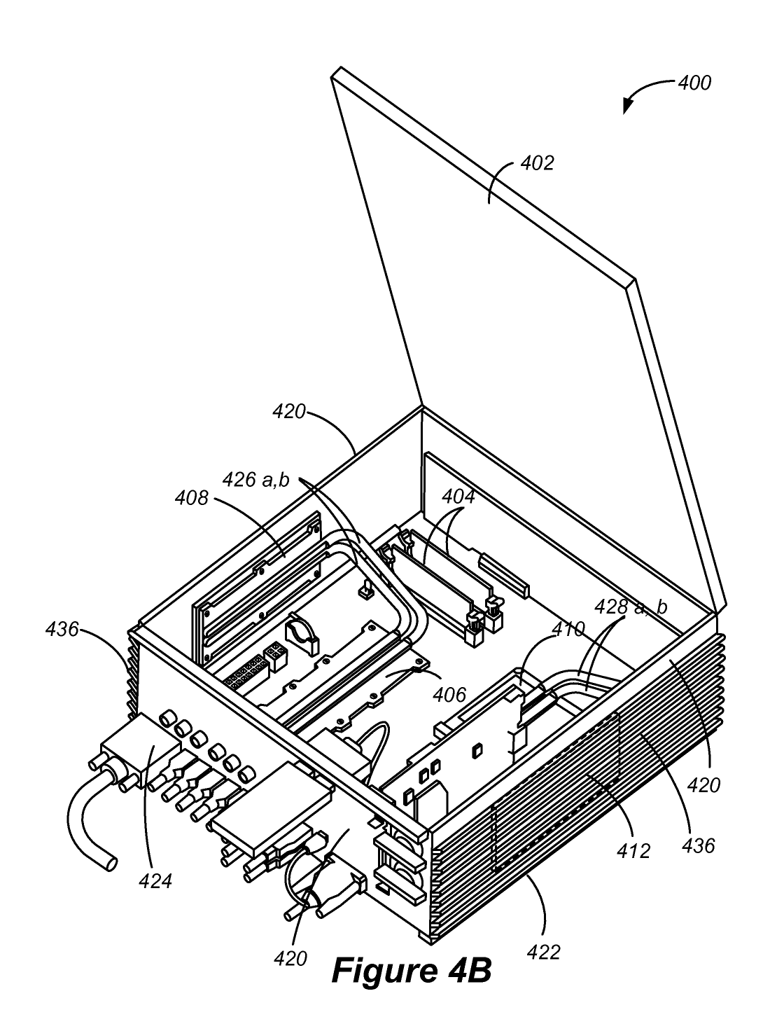

FIGS. 4A and 4B show different views of a cooling chassis 400 including an access panel 402 in accordance with one implementation. (The access panel is not shown in FIG. 4A for purposes of clarity). The chassis 400 is configured to house a plurality of internal electronic components of the gaming machine. For instance, the chassis 400 houses memory modules 404, a CPU 414 (shown with dotted lines), a GPU 416 (shown with dotted lines), and a PCH 418 (shown with dotted lines).

In some implementations, the chassis 400 may be a stand-alone component case with four side walls 420, a bottom wall 422 and the access panel or lid 402. The chassis walls and the access panel may be of a thermal conductive material such that the chassis 400 is able to transmit thermal energy out of the chassis. For example, the chassis walls and the access panel may be made of copper, aluminum, steel, or some other thermally conductive material.

The chassis 400 is fitted and housed in the interior of the main cabinet 4 of the gaming machine 200. In some implementations, the main cabinet 4 includes different compartments at different locations within the gaming machine. For example, one compartment may be a shelf or an enclosure within the main cabinet 4 to house the chassis 400.

In some implementations, the main cabinet 4 may include a CPU compartment to house the chassis 400. The CPU compartment includes a back panel with cut-outs to allow motherboard connectors to protrude into the compartment. The chassis 400 includes a plug 424 at a chassis wall 420 that connects to a motherboard connector to establish a connection with a motherboard and power the internal electronic components housed within the chassis. In other implementations, a compartment provides access to an electronic board mounted within the gaming machine. A cooling chassis housed in a compartment may include a cable or a plug that can be used to connect to the electronic board to power the internal electronic components housed within the chassis.

As FIGS. 4A and 4B illustrate, the chassis 400 may be a stand-alone component case that can easily fit within a compartment of a gaming machine cabinet. As such, a damaged chassis may easily be replaced with a new chassis. Additionally, this configuration provides the ability to update a gaming machine with an upgraded cooling chassis which may include newer internal electronic components, cooling assemblies and/or components programmed with updated software. Thus, a technician can easily service and upgrade a gaming machine.

Although FIGS. 4A and 4B depict a square cooling chassis, the chassis 400 may be of any shape and size. For example, the chassis may be rectangular or spherical shaped. The shape and size of a chassis may vary depending on the location, shape and size of compartments within a gaming machine cabinet.

The chassis 400 may include two cooling assemblies to ensure the operational temperatures of the internal electronic components are maintained. The first cooling assembly includes heat exchangers 406 and 408 and fluid communication paths 426a and 426b. The second cooling assembly includes heat exchangers 410 and 412 and fluid communication paths 428a and 428b. The heat exchangers may be heat spreaders or any other devices built for efficient heat transfer from one medium to another medium. Similar to the chassis walls, the heat exchangers may be constructed of thermal conductive materials such as copper and aluminum. Although FIGS. 4A and 4B show the cooling chassis 400 with two cooling assemblies, the cooling chassis may include one cooling assembly or more than two cooling assemblies to maintain the operational temperatures of internal electronic components housed within the chassis.

In some implementations, the heat exchanger 406 is coupled to the CPU 414 and GPU 416 to conduct heat away from the CPU and GPU. As illustrated by the dotted lines in FIG. 4A, the heat exchanger 406 may be placed on top of the CPU and GPU. The heat exchanger 406 is joined on top of the CPU and GPU by a thermal interface. The thermal interface may be formed by any thermal conductive material or surface that allows the heat generated by the CPU and GPU to be efficiently transferred to the heat exchanger 406. For example, the thermal interface used to join the heat exchanger 406 and the CPU and GPU may be thermal grease, a thermal pad or a thermal adhesive. In such a configuration, the heat exchanger 406 maintains a higher temperature than the heat exchanger 408 and may be thought of as a high temperature heat exchanger, while heat exchanger 408 may be thought of as a low temperature heat exchanger.

As discussed, the heat exchangers 406 and 408 are coupled via the fluid communication paths 426a and 426b. The fluid communication paths may be conduits, such as heat pipes, vapor chambers or any passageways, which allow for the efficient transfer of thermal energy between the two heat exchangers 406 and 408. The fluid communication paths may be constructed of copper, aluminum or any thermal conductive material. Additionally, each fluid communication paths 426a and 426b may contain a working fluid. The working fluid, for example, may be water, ethanol, acetone, sodium or some other coolant.

The fluid communication paths 426a and 426b each include a high temperature end 430 and a low temperature end 432. As illustrated in FIG. 4A, the high temperature end 430 is coupled to the heat exchanger 406, while the low temperature end 432 is coupled to the heat exchanger 408.

In such a configuration, as the CPU 414 and GPU 416 generate thermal energy, the heat exchanger 406 conducts heat away from the CPU 414 and GPU 416. Specifically, the working fluid in the fluid communication path 426a and 426b at the high temperature end 430 is converted into a vapor by absorbing thermal energy from the heat exchanger 406. The vapor is transferred via the fluid communication paths 426a and 426b to the heat exchanger 408.

At the low temperature end 432, the vapor condenses back into a liquid as thermal energy is transferred to the heat exchanger 408. After the vapor condenses back into a liquid, the working fluid flows back, either by capillary action or by gravity action, to the high temperature end 430 via the fluid communication paths 426a and 426b. In some implementations, the fluid communications paths 426a and 426b may include a wick that exerts capillary pressure on the working fluid to cause it to flow back to the high temperature end 430. The wick may be a sintered metal powder wick, a grooved wick, a metal mesh wick or any suitable wick configuration. In other implementations, the working fluid may flow back to the high temperature end 430 by gravity action. In such a configuration, the heat exchanger 408 is oriented at a greater elevation than the heat exchanger 406 to cause the working fluid to flow back to the high temperature end 430 by gravity.

As the working fluid cycles simultaneously between vapor and liquid phases within the fluid communication paths 426a and 426b, thermal energy from the heat exchanger 406 is transferred to the heat exchanger 408. Although FIGS. 4A and 4B show two fluid communication paths, a single fluid communication path may be used to connect the heat exchangers 406 and 408. The number of fluid communication paths utilized within a cooling chassis may depend on the amount of thermal energy dissipated by the internal electronic components and/or the ability of a fluid communication path to transfer thermal energy.

At the heat exchanger 408 side of the cooling assembly, thermal energy is transferred outside of the cooling chassis 400 via conduction, convection and/or radiation. In some implementations, the heat exchanger 408 is situated proximate to a wall of the chassis 420 to transfer thermal energy to an exterior region of the chassis 400 as depicted by the arrows 434. For example, the heat exchanger 408 may be coupled to one of the side walls 420 using a thermal interface, such as thermal grease. The thermal interface facilitates the transfer of thermal energy from the heat exchanger 408 through the side wall 420 to an exterior region of the chassis 400 such as the interior of the gaming machine cabinet 200. By placing the heat exchanger 408 near one of the chassis walls 420 to facilitate the transfer of thermal energy out of the chassis 400, a completely fanless cooling mechanism is achieved, thereby increasing the reliability and the lifespan of the internal electronic components located within the chassis.

In some implementations, the chassis walls may include cooling fins 436 (shown in FIG. 4B). The cooling fins are used to facilitate the transfer of thermal energy from the heat exchanger 408 to an exterior region of the chassis 400. The cooling fins increase the surface area of the chassis walls to allow for more efficient heat transfer. Like the chassis walls, the cooling fins are made of thermal conductive materials, such as copper or aluminum, to efficiently transfer thermal energy. Additionally, the cooling fins utilized may be pin, straight or flared cooling fins or a combination of such fins. In some implementations, each wall of the chassis may include cooling fins. In other implementations, the cooling fins may be located at certain specific side wall portions of the chassis 400. For example, the cooling fins may be located at a region of a chassis wall that corresponds to the height and width of the heat exchanger 408.

The heat exchangers 410 and 412 and the fluid communication paths 428a and 428b may be configured and provide similar functions as described with reference to heat exchangers 406 and 408 and fluid communication paths 426a and 426b.

In some implementations, the walls of the chassis 400 (e.g., the walls 420 and access panel 402) may be constructed to prevent air or limit the amount of air which can enter the interior region of the chassis. For example, the chassis walls may have no vents or filters. Utilizing sealed walls or nearly air tight walls reduces the internal electronic components' and heat dissipating devices' exposure to ambient air. As such, the internal electronic components and the heat dissipating devices are not exposed to dust and/or other particulate contaminates that may damage the components and the heat dissipating devices. Thus, the reliability and the life expectancy of the internal electronic components and the heat dissipating devices are increased.

Additionally, in this configuration, the chassis walls act as a conductive medium to transmit thermal energy out of the chassis, thereby eliminating the need for an airflow path within the chassis and, thus, further reducing the exposure of components and devices within the chassis to dust and other contaminates.

In some implementations, the access panel 402 may remain hinged to the chassis 400 when it is in an open position. In other implementations, the access panel 402 may be completely disengaged from the chassis 400 when in the open position.

In some implementations, the heat exchangers 408 and 412 may be further situated in a location away from the access panel 402. For example, the heat exchangers 408 and 412 may be coupled to a lower portion of the chassis wall 420. In another example, the heat exchangers 408 and 412 may be coupled to the bottom chassis wall 422. Moreover, the access panel is not coupled to the heat exchangers or to any of the cooling assemblies within the chassis. As such, a technician may service the internal components of the chassis without disassembling the cooling assembly or ruining a thermal interface between the cooling assembly and a chassis wall. This reduces the need to replace parts during service operations.

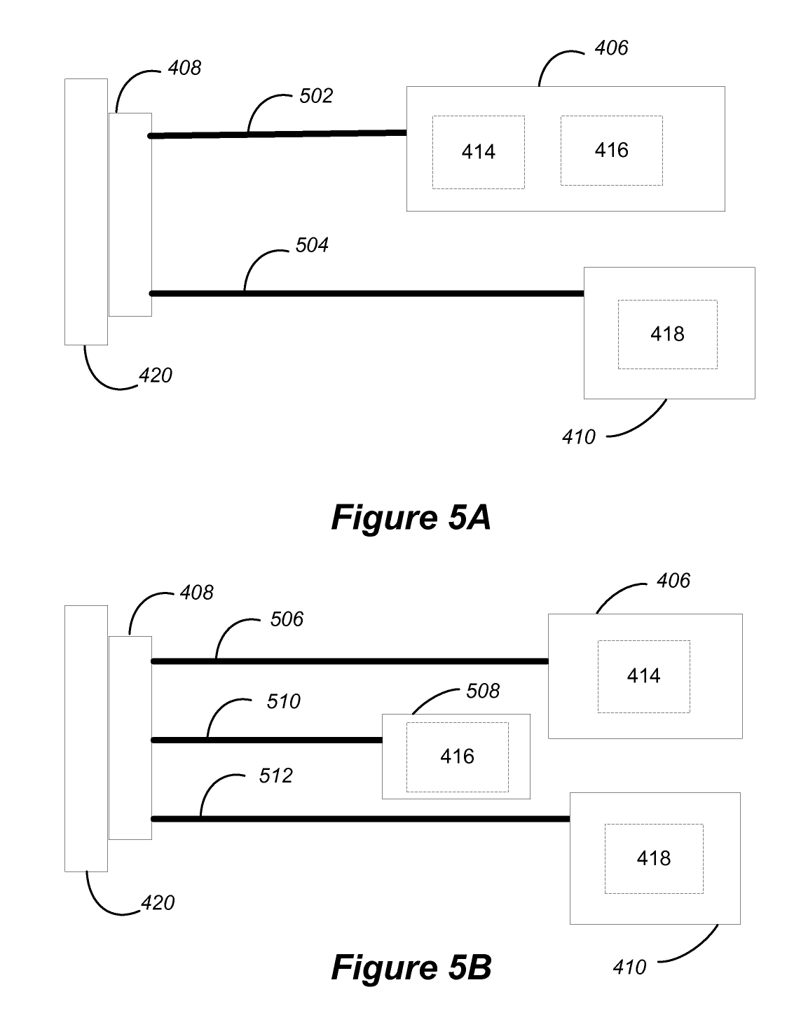

FIGS. 5A-5B illustrate some examples of different implementations of a cooling assembly. For instance, FIG. 5A illustrates the low temperature heat exchanger 408 coupled to two high temperature heat exchangers 406 and 410 via fluid communication paths 502 and 504, respectively. The low temperature heat exchanger 408 is further coupled to the chassis wall 420. In this embodiment, a single heat exchanger 408 may be used to conduct thermal energy from an interior region of the chassis 400 to an exterior region of the chassis. In FIG. 5B, the low temperature heat exchanger 408 is coupled to the high temperature heat exchanger 406 via a fluid communication path 506. The high temperature heat exchanger 406 is coupled to a single internal electronic component, such as the CPU 414. The low temperature heat exchanger 408 is further coupled to the high temperature heat exchangers 508 and 410 via fluid communication paths 510 and 512, respectively. The heat exchangers 508 and 410 may also be coupled to a single internal electronic component, such as the GPU 416 and the PCH 418, respectively.

Although FIGS. 5A and 5B illustrate examples of implementations of a cooling assembly within a cooling chassis, the cooling assemblies described herein may be configured in various other ways to cool the internal electronic components. For example, a single high temperature heat exchanger may be coupled to multiple low temperature heat exchangers via multiple fluid communication paths. In another example, the cooling assembly may not include a low temperature heat exchanger. For instance, with reference to FIG. 5A, the low temperature heat exchanger 408 may be eliminated. In such a configuration, the heat pipes 502 and 504 are situated proximate to the chassis wall. For example, the heat pipes 502 and 504 may be coupled or directly integrated into the chassis wall. As such, the chassis wall 420 functions as a low temperature heat exchanger by transferring thermal energy out of the chassis 400 by conduction, convection and/or radiation. Consequently, the chassis wall 420 serves a dual purpose. That is, the chassis walls functions as part of an enclosure for the internal electronic components as well as a thermal energy transfer medium.

Furthermore, FIGS. 5A-5B merely provide illustrations of a number of internal electronic components that may be coupled with high temperature heat exchangers. The number of internal electronic components coupled to a high temperature heat exchanger may depend on various factors, such as the location of an internal electronic component within a cooling chassis, power and electrical requirements of an internal electronic component, the amount of thermal energy dissipated by an internal electronic component, the distance between an internal electronic component and a fluid communication path, or other factors required to achieve optimal cooling efficiencies. Based on these optimization factors, multiple internal electronic components may be coupled with a single high temperature heat exchanger. In other instances, each internal electronic component may be coupled to a separate high temperature heat exchanger. As such, various configurations may be implemented to achieve the cooling chassis and systems described herein.

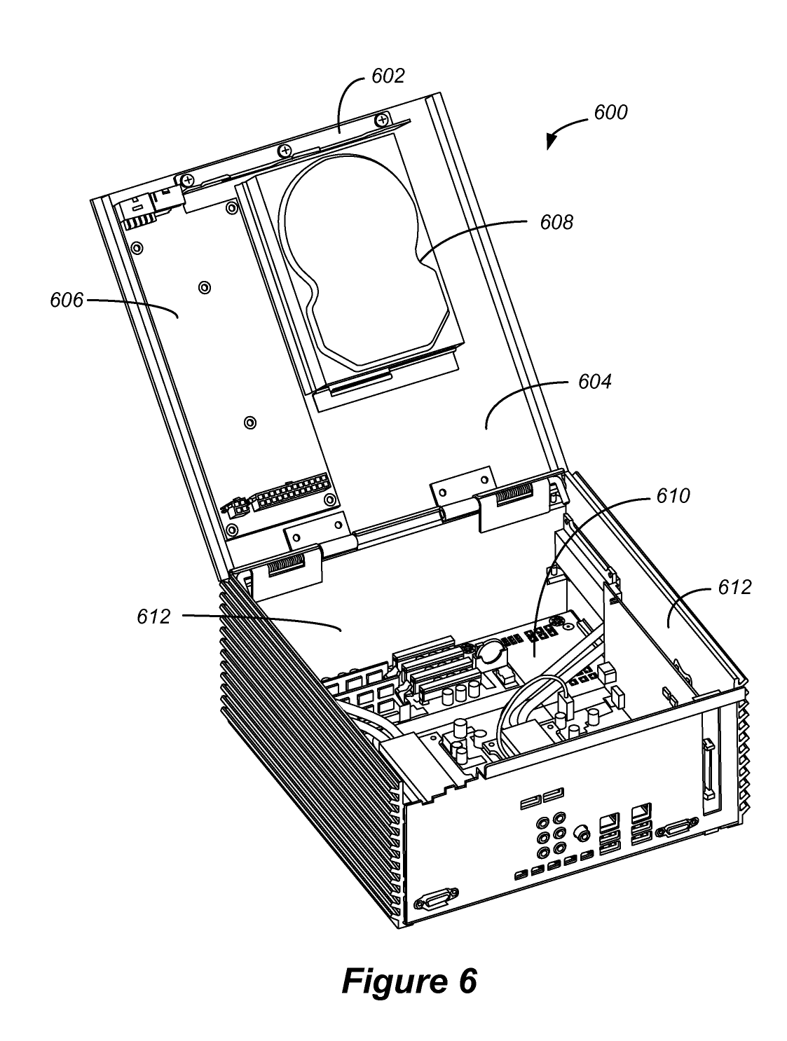

FIG. 6 shows a cooling chassis 600 in accordance with one implementation. Similar to the chassis 400, the chassis 600 is configured to house a plurality of internal electronic components of a gaming machine and utilize the cooling assemblies described with reference to FIGS. 4A and 4B.

The chassis 600 includes an access panel 602 that is similar to the access panel 402. In some implementations, the access panel 602 is configured as a platform to which internal electronic components may be coupled onto an interior side 604. For example, internal electronic components that dissipate minimal amounts of thermal energy (e.g., components that do not require a cooling assembly), such as a power supply printed circuit board (PCB) 606 and/or a hard drive 608, may be coupled to the access panel 602 via a thermal interface, such as thermal grease. The thermal interface facilitates the transfer of thermal energy generated by the power supply PCB 606 and the hard drive 608 via the access lid 602 to an exterior region of the chassis 600. As such, the access panel 602 functions as a thermal energy transfer medium. In some implementations, the exterior side of the access panel 602 (not shown) includes cooling fins to provide more efficient heat transfer from the interior region of the chassis 600 to the exterior region. The cooling fins may be similar to the cooling fins described with reference to FIGS. 4A and 4B.

Utilizing the access lid 602 as a platform and a thermal energy transfer medium provides a mechanism to ensure that the temperature in the interior region of the chassis 600 remains low. Typically, as internal electronic components generate thermal energy within a chassis, the air within the chassis 600 increases in temperature. If the air increases to significantly high temperatures (e.g., temperatures above the operational temperatures of the internal electronic components), the internal electronic components may fail. As such, coupling the internal electronic components to the access panel 602 allows heat to be directly conducted out of the chassis, thereby preventing the air temperature within the chassis from reaching undesirable temperature levels.

In some implementations, the power supply PCB 606 and the hard drive 608 are coupled to the access panel 602 such that the components move with the access panel. For example, the power supply PCB 606 and the hard drive 608 may be coupled to the access lid 602 using clips, push pins, screws, and/or any other mechanism which securely couples the internal electronic components to the access lid 602. By securely mounting the components 606 and 608 to the access panel 602, a technician may open the access lid 602 without the components 606 and 608 obstructing access to the interior region of the chassis.

In some implementations, the components 606 and 608 may include a harness which connects to a motherboard 610 within the chassis. For example, the harness may be a service loop (not shown). In another example, the components 606 and 608 may connect to the motherboard 610 via a blind mate connector-connector arrangement.

In some implementations, the components 606 and 608 may be coupled to a chassis wall 612 instead of the access panel 602. As discussed with reference to the access panel 602, the components 606 and 608 are coupled to the chassis wall 612 using a thermal interface and are securely mounted to the chassis wall using clips, screws, and/or push pins. The arrangement and location of the internal electronic components on the chassis wall 612 and/or on the access panel 602 may vary depending on which arrangement achieves the greatest cooling efficiencies.

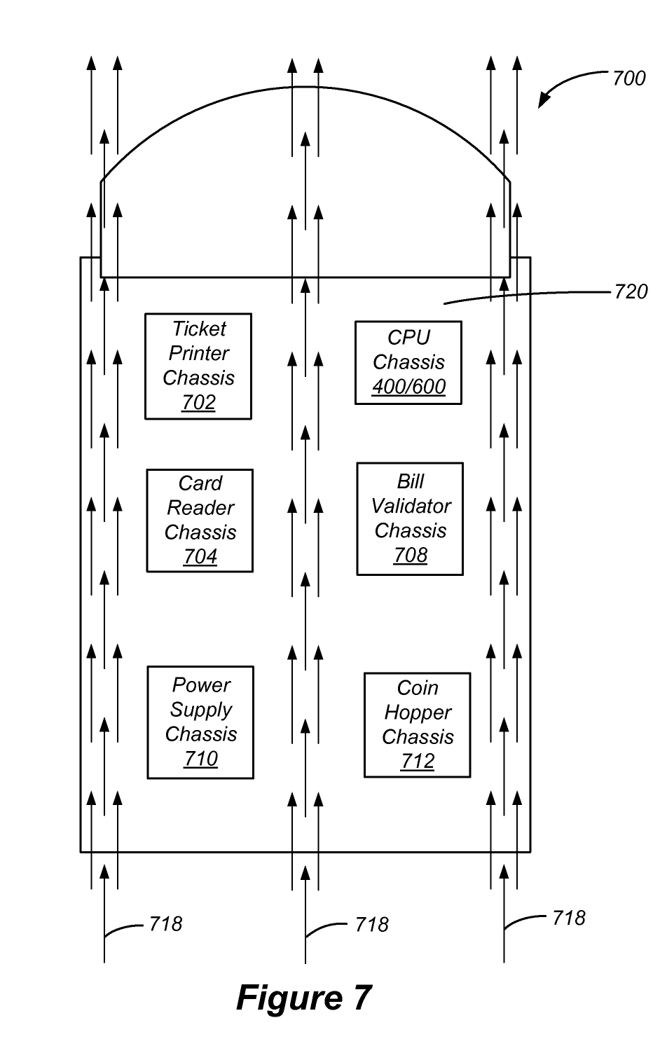

FIG. 7 shows an interior of a gaming machine cabinet 700 housing a plurality of internal electronic gaming components each housed within its own individual chassis. Each chassis depicted may utilize the cooling assemblies described in FIGS. 4A and 4B. The gaming machine cabinet 700 comprises a ticket printer chassis 702, the CPU chassis 400/600, a card reader chassis 704, a bill validator chassis 708, a power supply chassis 710 and a coin hopper chassis 712.

In some implementations, the gaming machine 700 may have vents to allow cool air to flow through the gaming machine as described in FIGS. 2-3B. In some implementations, the gaming machine 700 may have an air intake vent (not shown) at the bottom of the gaming machine to introduce fresh air into the gaming machine 700. The gaming machine 700 may also include an air exhaust vent to exhaust air from the gaming machine. The air exhaust vent (not shown) may be located at the top box of the gaming machine. In some implementations, the gaming machine 700 may have multiple air intake vents and air exhaust vents strategically placed to cool different chassis housed in the gaming machine.

In some implementations, the plurality of chassis housed in the gaming machine 700 may be cooled by natural convection. That is, ambient air may be drawn in from the intake vent at the bottom of the gaming machine and distributed within the gaming machine to cool the different chassis. Arrows 718 depict air flowing through the intake vent to the exhaust vent as the air 718 cools the chassis within the gaming machine 700. In such a configuration, a completely fanless cooling mechanism is provided using natural convection to cool the chassis within the gaming machine in combination with the cooling assemblies described in FIGS. 4A-4B. A completely fanless cooling system eliminates the need to periodically service and replace fans within a gaming machine that may have been damaged. In some other implementations, a combination of natural and forced convection may be provided with the assistance of cooling fans. Cooling fans may be strategically placed within the cabinet of the gaming machine 700 to draw cool air into the gaming machine and expel warm air from the gaming machine.

In some implementations, the gaming machine 700 does not include vents or fans. In such an implementation, thermal energy generated within the gaming machine 700 is transferred to an exterior region of the gaming machine by conduction, convection and/or radiation. For example, chassis 400/600 may be coupled to a back wall 720 of the gaming machine 700 via a thermal interface. The back wall 720 may be constructed of copper, aluminum or any other suitable thermal conductive material. As such, thermal energy is transferred through the back wall 720 to an exterior region of the gaming machine 700. Similar to the chassis walls 420 and 612, the gaming machine walls act as thermal energy transfer mediums.

Additionally, the air circulating around and over the gaming machine cools the gaming machine and the chassis within the gaming machine, thereby eliminating the need for vents and fans to cool the interior region of the gaming machine. This reduces the exposure of components housed within a gaming machine to dust and contaminates. Furthermore, the problem of dust and contaminates forming deposits on vents and fans of a gaming machine and thus impeding airflow into the gaming machine is also eliminated. As a result, the life expectancies of chassis, cooling assemblies and internal electronic components housed within the gaming machine are extended.

In some implementations, the cooling assemblies and internal electronic components described in FIGS. 4A & 4B may be coupled to a gaming machine wall via a thermal interface. For instance, with reference to FIGS. 4A & 4B, the heat exchanger 408 may be coupled to the back wall 720. The thermal energy generated by the CPU 414 and the GPU 416 is transferred from the heat exchanger 408 to the back wall 720.

In some instances, the fluid communications paths 426a and 426b may be directly integrated into a gaming machine wall to eliminate the need for the heat exchanger 408. The gaming machine wall then functions as a low temperature heat exchanger by transferring thermal energy directly to an exterior region of the gaming machine. As such, the gaming machine functions as an enclosure to house a variety of internal electronic components as well as a thermal energy transfer medium. In such an implementation, the gaming machine 700 is configured to be air tight to prevent damage to the cooling assemblies and to the internal electronic components due to dust and particulate contamination.

Any of the above embodiments may be used alone or together with one another in any combination. Although various embodiments may have been motivated by various deficiencies with the prior art, which may be discussed or alluded to in one or more places in the specification, the embodiments do not necessarily address any of these deficiencies. In other words, different embodiments may address different deficiencies that may be discussed in the specification. Some embodiments may only partially address some deficiencies or just one deficiency that may be discussed in the specification, and some embodiments may not address any of these deficiencies.

While various embodiments have been described herein, it should be understood that they have been presented by way of example only, and not limitation. Thus, the breadth and scope of the present application should not be limited by any of the embodiments described herein, but should be defined only in accordance with the following and later-submitted claims and their equivalents.

What is claimed is:

1. A gaming machine, comprising:
an input device configured to receive an indication of value for play of a wager-based game in which one or more game outcomes can be provided responsive to a wager;
an output device configured to output an indication of value in association with play of the wager-based game;
a display configured to display information associated with the wager-based game; and
a chassis configured to house an internal electronic component of the gaming machine, the chassis including:
a chassis wall and an access panel to provide access to the internal electronic component, and
a cooling assembly, the cooling assembly including a first heat exchanger coupled to the internal electronic component and a fluid communication path situated proximate to the chassis wall, the fluid communication path being configured to transfer thermal energy from the first heat exchanger to an exterior region of the chassis via the chassis wall to maintain an operational temperature of the internal electronic component.

2. The gaming machine of claim 1, wherein the fluid communication path includes a high temperature end and a low temperature end and the fluid communication path is configured to house a working fluid.

3. The gaming machine of claim 2, wherein the working fluid is at least one of water, ethanol, acetone or sodium.

4. The gaming machine of claim 2,
wherein the first heat exchanger is coupled to the fluid communication path at the high temperature end; and
wherein the first heat exchanger is configured to transfer thermal energy from the internal electronic component to the high temperature end of the fluid communication path to cause the working fluid to evaporate.

5. The gaming machine of claim 2,
wherein the low temperature end of the fluid communication path is coupled to the chassis wall; and
wherein the chassis wall is configured to receive thermal energy from the first heat exchanger at the low temperature end of the fluid communication path to cause the vapor to condense back into the working fluid.

6. The gaming machine of claim 2,
wherein the cooling assembly further includes a second heat exchanger situated proximate to the chassis wall at the low temperature end of the fluid communication path; and
wherein the first heat exchanger is coupled to the second heat exchanger, the second heat exchanger being configured to receive thermal energy from the first heat exchanger via the fluid communication path and transfer thermal energy to the chassis wall.

7. The gaming machine of claim 6, wherein the second heat exchanger is configured to be thermally coupled to the chassis wall to transfer thermal energy by conduction through the chassis wall.

8. The gaming machine of claim 7,
wherein the second heat exchanger is thermally coupled to the chassis wall by a thermal interface, the thermal interface being at least one of: a thermal grease, a thermal pad or a thermal adhesive.

9. The gaming machine of claim 6, wherein the second heat exchanger is positioned at a location away from the access panel to provide an unobstructed access to the internal electronic component housed within the chassis.

10. The gaming machine of claim 1, wherein the chassis wall includes cooling fins to facilitate the transfer of thermal energy to the exterior region of the chassis.

11. The gaming machine of claim 1, wherein the chassis is configured to prevent air from entering into an interior region of the chassis when the access panel is in a closed position.

12. The gaming machine of claim 1,
wherein the first heat exchanger is coupled to a plurality of internal electronic components located within the chassis based on an optimization factor;
wherein the optimization factor is at least one of: a location of each internal electronic component of the plurality of internal electronic components, a power requirement of each internal electronic component of the plurality of electronic components, and an amount of thermal energy dissipated by each internal electronic component of the plurality of electronic components.

13. The gaming machine of claim 1, wherein the internal electronic component is at least one of a central processing unit, a graphical processing unit or a platform controller hub.

14. A chassis for use with a gaming machine, the chassis comprising:
a chassis wall and an access panel to provide access to an internal electronic gaming machine component located within the chassis; and
a cooling assembly, the cooling assembly including a first heat exchanger thermally coupled to the internal electronic gaming machine component and a fluid communication path situated proximate to the chassis wall, the fluid communication path being configured to transfer thermal energy from the first heat exchanger to an exterior region of the chassis via the chassis wall to maintain an operational temperature of the internal electronic gaming machine component.

15. The gaming machine of claim 14, wherein the fluid communication path includes a high temperature end and a low temperature end and the fluid communication path is configured to house a working fluid.

16. The gaming machine of claim 15,
wherein the first heat exchanger is coupled to the fluid communication path at the high temperature end; and
wherein the first heat exchanger is configured to transfer thermal energy from the internal electronic component to the high temperature end of the fluid communication path to cause the working fluid to evaporate.

17. The gaming machine of claim 15,
wherein the low temperature end of the fluid communication path is coupled to the chassis wall; and
wherein the chassis wall is configured to receive thermal energy from the first heat exchanger at the low temperature end of the fluid communication path to cause the vapor to condense back into the working fluid.

18. The gaming machine of claim 15,
wherein the cooling assembly further includes a second heat exchanger situated proximate to the chassis wall at the low temperature end of the fluid communication path; and
wherein the first heat exchanger is coupled to the second heat exchanger, the second heat exchanger being configured to receive thermal energy from the first heat exchanger via the fluid communication path and transfer thermal energy to the chassis wall.

19. The chassis of claim 14, wherein another internal electronic gaming machine component is coupled to the access panel via a thermal interface.

20. The chassis of claim 14, wherein the chassis is a stand-alone case housed in a compartment of the gaming machine.
